(19) United States
(12) Patent Application Publication
(10) Pub. No.: US 2019/0058150 A1
(43) Pub. Date: Feb. 21, 2019

(54) DISPLAY DEVICE

(71) Applicant: Samsung Display Co., Ltd., Yongin-si (KR)

(72) Inventor: Jae Sung LEE, Cheonan-si (KR)

(21) Appl. No.: 15/893,219

(22) Filed: Feb. 9, 2018

(30) Foreign Application Priority Data
Aug. 18, 2017 (KR) 10-2017-0104779

(51) Int. Cl. H01L 51/52; F28F 21/02

(52) U.S. Cl. CPC H01L 51/529; H01L 51/5246; H01L 27/3244; H01L 2251/5338; F28F 21/02

(57) ABSTRACT

A display device includes: a display panel including a flat area and a bending area located around the flat area; and a panel lower sheet arranged on the display panel and overlapping the flat area, and the panel lower sheet includes a support member including at least one through hole and a heat radiation member arranged in the at least one through hole.

### CROSS REFERENCE TO RELATED APPLICATION

This application claims priority to and the benefit of Korean Patent Application No. 10-2017-0104779, filed on Aug. 18, 2017 in the Korean Intellectual Property Office, the entire disclosure of which is incorporated herein by reference.

### BACKGROUND

### 1. Field

Aspects of embodiments of the present invention relate to a display device.

### 2. Description of the Related Art

With the development of information society, demands for display devices for displaying images are increasing in various forms. In particular, an organic light emitting display device is applied to various products including smartphones because it has excellent luminance, driving voltage and response speed and is capable of multi-color display.

The organic light emitting display device is generally used for portable electronic appliances, such as smartphones, and is easily exposed to external impact. Further, in the organic light emitting display device, when excessive heat is generated in an organic light emitting element or a driving chip for driving the same, the element may be damaged. In order to protect against such a danger, a functional sheet having functions of heat radiation and buffering is attached to the lower surface of a display panel.

The functional sheet should have a thickness greater than a certain thickness in order to perform its function. In this case, a thickness of the display device is increased by the thickness of the functional sheet, which may make it difficult to make the display device thinner, smaller, and lighter.

### SUMMARY

According to an aspect of embodiments of the present invention, a display device is improved in a heat radiation function without increasing thickness.

However, aspects of the present invention are not restricted to those set forth herein. The above and other aspects of the present invention will become more apparent to one of ordinary skill in the art to which the present invention pertains by referencing the description of some exemplary embodiments of the present invention provided below.

According to one or more exemplary embodiments of the present disclosure, a display device comprises a display panel including a flat area; and a panel lower sheet arranged on the display panel and overlapping the flat area, wherein the panel lower sheet includes a support member including at least one through hole and a heat radiation member arranged in the at least one through hole.

According to one or more exemplary embodiments of the present disclosure, a display device comprises a display panel including a flat area; and a panel lower sheet arranged on the display panel and overlapping the flat area, wherein the panel lower sheet includes a support member including at least one concave groove and a heat radiation member arranged in the at least one concave groove.

### BRIEF DESCRIPTION OF THE DRAWINGS

The above and other aspects and features of the present invention will become more apparent by describing in further detail some exemplary embodiments thereof with reference to the attached drawings, in which:

FIG. 1 is an exploded perspective view of a display device according to an embodiment;

FIG. 2 is a cross-sectional view of the display device of FIG. 1, taken along the line II-II′;

FIG. 3 is a partial enlarged cross-sectional view of a display panel of the display device of FIG. 1;

FIG. 4 is an exploded perspective view of a second panel lower sheet of the display device of FIG. 1;

FIG. 5 is a perspective view of the second panel lower sheet of FIG. 4;

FIG. 6 is a cross-sectional view of the second panel lower sheet of FIG. 5, taken along the line VI-VI′;

FIG. 7 is an exploded perspective view of a second panel lower sheet of a display device, according to another embodiment;

FIG. 8 is a perspective view of the second panel lower sheet of FIG. 7;

FIG. 9 is a cross-sectional view of the second panel lower sheet of FIG. 8, taken along the line IX-IX′;

FIGS. 10 to 12 are perspective views showing shapes and arrangements of through holes of second panel lower sheets according to various embodiments;

FIG. 13 is an exploded perspective view of a display device according to another embodiment;

FIG. 14 is an exploded perspective view of a display device according to another embodiment; and

FIG. 15 is an exploded perspective view of a display device according to another embodiment.

### DETAILED DESCRIPTION

Aspects and features of the present disclosure and methods of accomplishing the same may be understood more readily by reference to the following description of some exemplary embodiments and the accompanying drawings. The present disclosure may, however, be embodied in many different forms and should not be construed as being limited to the exemplary embodiments set forth herein. Rather, these exemplary embodiments are provided so that this disclosure will be thorough and complete and will fully convey the concept of the present disclosure to those skilled in the art.

Cases in which elements or layers are referred to as being located “on” other elements or layers include all the cases in which other layers or other elements are interposed directly on or between other elements. Meanwhile, cases in which the elements are referred to as being “directly on” indicate that no other element or layer is interposed therebetween. Same reference numerals refer to the same or like constituent elements throughout the specification. The term “and/or” includes each and every combination of one or more of the referenced items.

It is to be understood that, although the terms “first,” “second,” etc. may be used herein to describe various elements, these elements should not be limited by these terms. These terms are used to distinguish one element from another element. Thus, a “first” element discussed below could be termed a “second” element without departing from the teachings of the present invention.

In this specification, a first direction X is any one direction in the plane, a second direction Y is a direction intersecting the first direction X in the plane, and a third direction Z is a direction perpendicular to the plane.

Like reference numerals designate like or similar elements throughout the specification.

Herein, some embodiments of the present invention will be described with reference to the attached drawings.

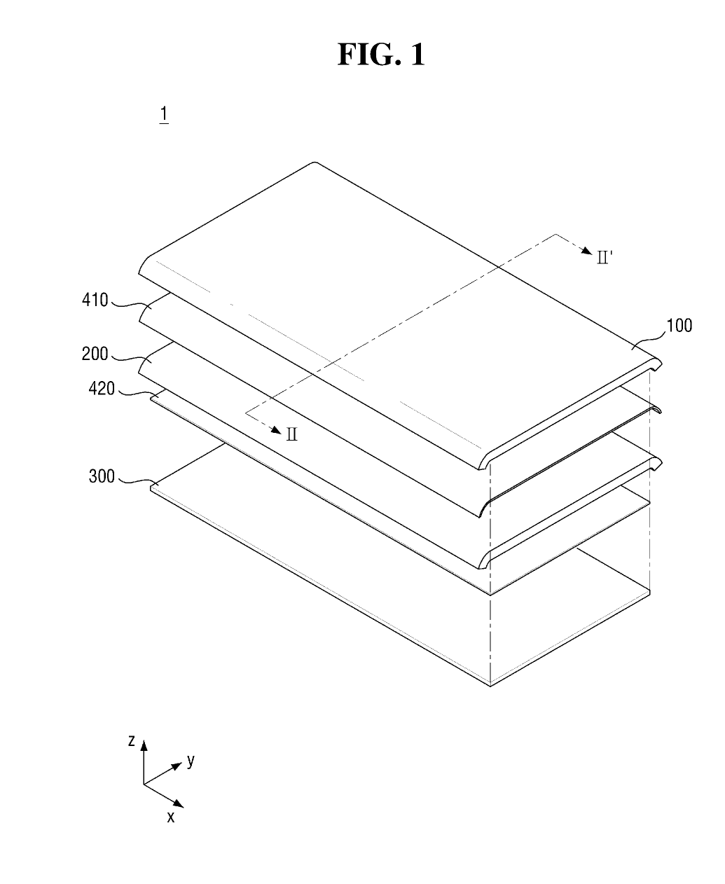

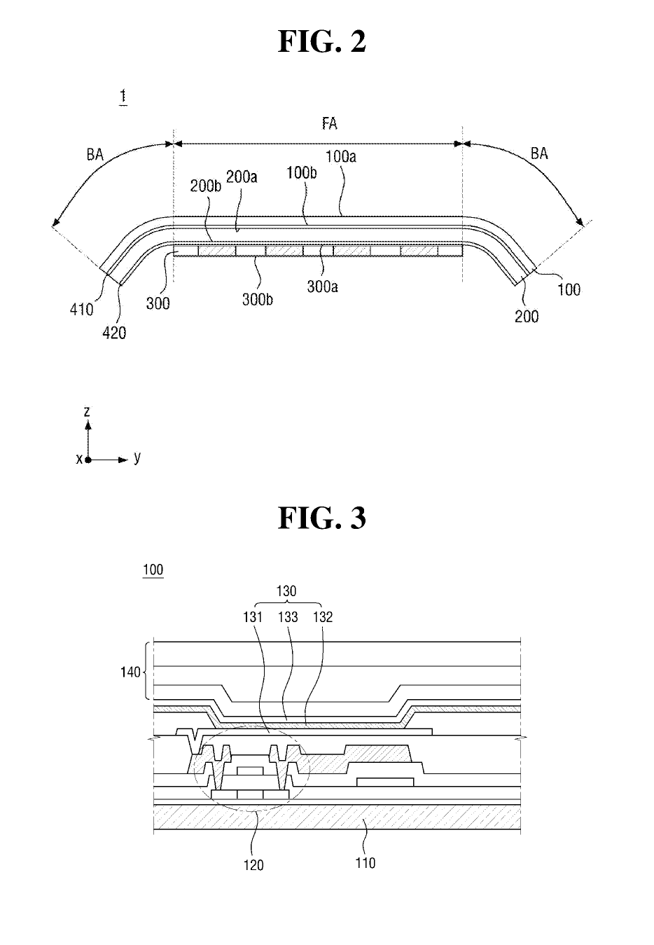

FIG. 1 is an exploded perspective view of a display device according to an embodiment. FIG. 2 is a sectional view of the display device of FIG. 1, taken along the line II-II′.

Referring to FIGS. 1 and 2, a display device 1 includes a display panel 100, a first panel lower sheet 200 disposed under the display panel 100, and a second panel lower sheet 300 disposed under the first panel lower sheet 200. Unless otherwise defined, in this specification, the terms “upper portion,” “top,” and “upper surface” refer to a display surface side with respect to the display panel 100, and the terms “lower portion,” “bottom,” and “lower surface” refer to an opposite side of the display surface side with respect to the display panel 100.

In an embodiment, the display device 1 may have a rectangular shape in a plan view. The display device 1 may include both long sides disposed along the first direction X and both short sides disposed along the second direction Y. A corner where the long side and short side of the display device 1 meet each other may be a right angle, but is not limited thereto, and may be a curved surface. The planar shape of the display device 1 is not limited to the illustrated one, and may be circular or may have other shapes.

The display device 1 may include a flat area FA and a bending area BA connected to the flat area FA and located around (e.g., at opposite sides of) the flat area FA. The flat area FA is generally located on one plane. The bending area BA is not located on the same plane as the flat area FA. For example, the bending area BA may be bent or warped in a downward direction from a plane where the flat area FA is located.

In an embodiment, the bending area BA may include an outwardly convexly curved surface. In another embodiment, the bending area BA may have a flat surface, but the flat surface of the bending area BA may be located on a plane having an angle relative to the plane of the flat area FA.

In an embodiment, the bending area BA may be located at both long sides of the rectangular display device 1 or at one side thereof. In an embodiment, although not shown in the drawings, the short side of the display device 1 may also be bent.

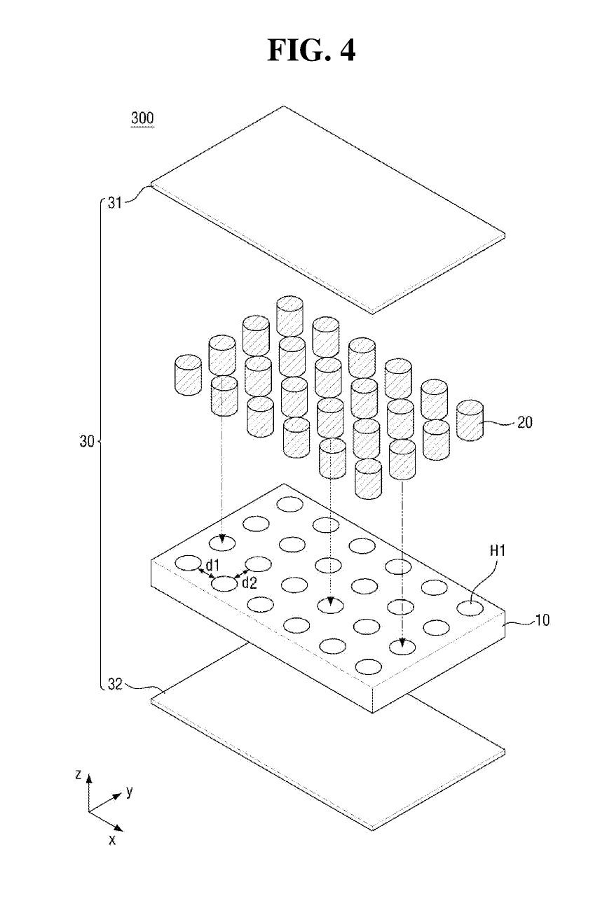

The display panel 100 may be located over the flat area FA and the bending area BA. The display panel 100 is a panel for displaying a screen or an image. In an embodiment, for example, an organic light emitting display panel may be used as the display panel 100. In the following embodiments, there is exemplified a case in which an organic light emitting display is used as the display panel 100. However, the present invention is not limited thereto, and different kinds of display panels, such as a liquid crystal display panel and an electrophoretic display panel, may be used as the display panel. According to an embodiment, an internal structure of the display panel 100 will be described with reference to FIG. 3.

FIG. 3 is a partial enlarged cross-sectional view of the display panel 100.

Referring to FIG. 3, according to an embodiment, the display panel 100 includes a plurality of organic light emitting elements 130 disposed on a substrate 110. The substrate 110 may be a rigid substrate made of glass or the like, or may be a flexible substrate made of polyimide or the like. When a polyimide substrate is used as the substrate 110, the display panel may be bent, warped, folded, or rolled.

The organic light emitting element 130 include a first electrode 131 and a second electrode 133 facing each other, and an organic layer 132 disposed therebetween. The first electrode 131 may be a pixel electrode provided for each pixel, and may be driven by a thin film transistor 120. The second electrode 133 may be a common electrode formed integrally without distinction of pixels.

The first electrode 131 may be an anode electrode made of a metal having a high work function, and the second electrode 133 may be a cathode electrode made of a metal having a low work function.

The organic layer 132 is disposed between the first electrode 131 and the second electrode 133. The organic layer 132 includes an organic light emitting layer. The organic light emitting layer may include a red organic light emitting layer disposed in a red pixel, a green organic light emitting layer disposed in a green pixel, and a blue organic light emitting layer disposed in a blue pixel. As another example, the organic light emitting layer may be formed by laminating two or more organic light emitting layers to emit white light.

The organic light emitting element 130 may be sealed by a thin film encapsulation layer 140.

In an embodiment, the thin film encapsulation layer 140 may have a structure in which an organic layer and an inorganic layer are alternately laminated. In an embodiment, the organic layer may be replaced with a hexamethyldisiloxane (HMDSO) layer.

In an embodiment, the edge portion of the substrate 110 may be in contact with the thin film encapsulation layer 140, and a region where the organic light emitting element 130 is located between the substrate 110 and the thin film encapsulation layer 140 is sealed. In this embodiment, there is exemplified a case in which the thin film encapsulation layer 140 is applied as the structure sealing the organic light emitting element 130, but the present invention is not limited thereto, and the organic light emitting element 130 may also be sealed by applying an upper substrate facing the substrate 110 and a sealing portion.

The transistor 120 operates as a heating element during a driving process of the display device to generate heat. When an internal temperature of the display panel 100 is maintained at a high temperature, the transistor 120, the organic light emitting element 130, and the like may be deteriorated, so as to cause the damage of the display panel 100. Particularly, in a case in which the substrate 110 is made of polyimide, heat diffusion toward the lower side of the substrate 110 may not be performed well, compared to a case in which the substrate 110 is made of glass. In the case of the polyimide substrate 110, the internal temperature of the display panel 100 may be maintained at a high temperature, compared to the case of the glass substrate 110. For example, in the case of the polyimide substrate 110, the internal temperature of the display panel 100 may be about 5° C. higher than that of the glass substrate 110, and deterioration of the display panel 100 may be accelerated. Accordingly, the display device 1 may further include a second panel lower sheet 300 having a heat radiation function. Further details of the second panel lower sheet 300 will be described later.

Referring to FIGS. 1 and 2 again, the first and second panel lower sheets 200 and 300 are disposed under the display panel 100. The first and second panel lower sheets 200 and 300 can perform a buffering function, a strength reinforcing function, a heat radiation function, an electromagnetic wave blocking function, and the like.

The panel lower sheets 200 and 300 may include the first panel lower sheet 200 and the second panel lower sheet 300. The first panel lower sheet 200 may be a layer performing a buffering function. The first panel lower sheet 200 may serve to absorb external impacts and prevent or substantially prevent the display device 1 from being damaged. That is, the first panel lower sheet 200 may absorb the impact applied to the display device 1, thereby improving impact resistance. The first panel lower sheet 200 may be formed of a single layer or a plurality of laminated films. The first panel lower sheet 200 may contain a material such as polyethylene terephthalate (PET), polyimide (PI), polyurethane (PU), or polyethylene (PE).

The first panel lower sheet 200 may be located over the flat area FA and the bending area BA. The first panel lower sheet 200 may have substantially the same size as the display panel 100 and is disposed to overlap the display panel 100, and the side surfaces of the first panel lower sheet 200 and the side surfaces of the display panel 100 may be aligned, but the present invention is not limited thereto.

An inter-panel-sheet bonding layer 410 may be disposed between the first panel lower sheet 200 and the display panel 100. The first panel lower sheet 200 may be attached to the lower portion of the display panel 100 through the inter-panel-sheet bonding layer 410. In this embodiment, there is exemplified a case in which the inter-panel-sheet bonding layer 410 is provided as a separate member from the first panel lower sheet 200, but the inter-panel-sheet bonding layer 410 may be included in the first panel lower sheet 200 as a top bonding layer.

When the display panel 100 includes upper surface 100a and lower surface 100b facing each other and the first panel lower sheet 200 includes upper surface 200a and lower surface 200b facing each other, the lower surface 100b of the display panel 100 and the upper surface 200a of the first panel lower sheet 200 may be in contact with the inter-panel-sheet bonding layer 410, respectively.

The inter-panel-sheet bonding layer 410 may contain a conductive material. In an embodiment, the inter-panel-sheet bonding layer 410 may be an optical clear adhesive (OCA) or a pressure-sensitive adhesive (PSA), and may also be a double-sided tape.

The second panel lower sheet 300 is disposed under the first panel lower sheet 200. The second panel lower sheet 300 may be a layer performing a supporting function and a heat radiation function. The second panel lower sheet 300 may be disposed in the flat area FA, and may not be disposed in the bending area BA. This arrangement may be employed when the second panel lower sheet 300 is made of a material such as stainless steel, graphite, or the like, which has relatively poor bending properties.

An inter-sheet bonding layer 420 may be disposed between the first panel lower sheet 200 and the second panel lower sheet 300. When the second panel lower sheet 300 includes a upper surface 300a and a lower surface 300b, the lower surface 200b of the first panel lower sheet 200 and the upper surface 300a of the second panel lower sheet 300 may be in contact with the inter-sheet bonding layer 420, respectively.

The inter-sheet bonding layer 420 is disposed to overlap the second panel lower sheet 300. The inter-sheet bonding layer 420 may have substantially a same size as the second panel lower sheet 300. That is, the inter-sheet bonding layer 420 may be disposed in the flat area FA, and may not be disposed in the bending area BA.

In an embodiment, the inter-sheet bonding layer 420 may be an optical clear adhesive (OCA) or a pressure-sensitive adhesive (PSA), and may also be a double-sided tape. The inter-sheet bonding layer 420 may be non-conductive. When the second panel lower sheet 300 contains a conductive material, the non-conductive inter-sheet bonding layer 420 can prevent or substantially prevent a short between the display panel 100 and the second panel lower sheet 300.

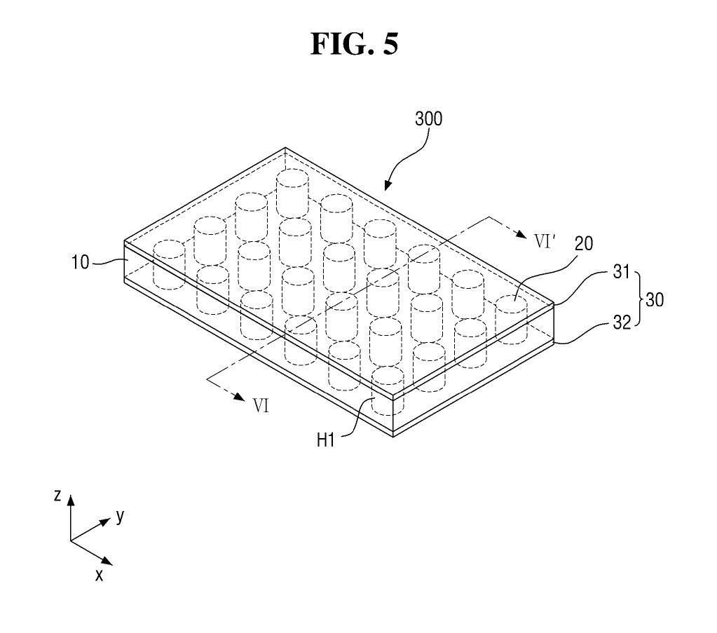

Herein, further details of the second panel lower sheet 300 will be described with reference to FIGS. 4 to 6.

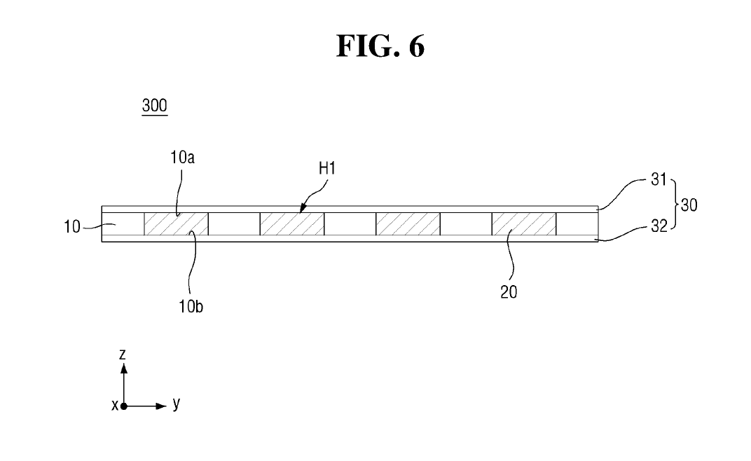

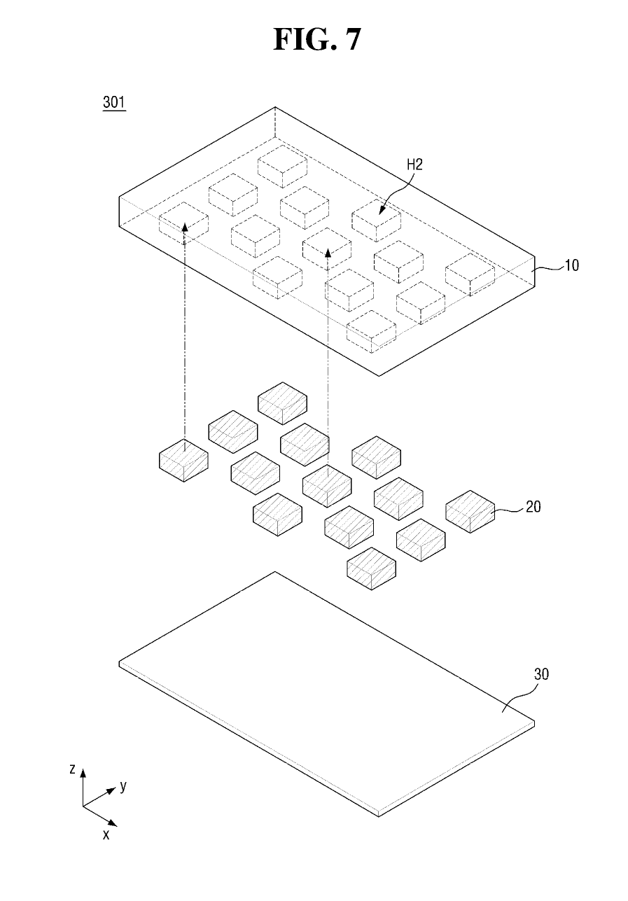

FIG. 4 is an exploded perspective view of the second panel lower sheet 300. FIG. 5 is a perspective view of the second panel lower sheet 300. FIG. 6 is a cross-sectional view of the second panel lower sheet 300, taken along the line VI-VI′ of FIG. 5.

Referring to FIGS. 4 to 6, the second panel lower sheet 300 may include a support member 10, a heat radiation member 20, a first protective layer 31, and a second protective layer 32.

The support member 10 supports the display panel 100 and improves the mechanical strength of the display device 1. In addition, the support member 10 has a certain level of thermal conductivity and thus can perform a heat radiation function. In an embodiment, the support member 10 may be made of stainless steel (SUS), but the present invention is not limited thereto.

The support member 10 may include a plurality of through holes H1. The plurality of through holes H1 provides spaces in which the heat radiation members 20 to be described later are to be inserted.

The plurality of through holes H1 may be regularly arranged on a plane. In an embodiment, the plurality of through holes H1 may be periodically arranged while being spaced apart from each other in parallel at predetermined intervals. In an exemplary embodiment, the through holes H1 of the support member 10 may be arranged in a substantially matrix shape while being spaced apart from each other in the first direction X and the second direction Y, which are orthogonal to each other. In the plurality of through holes H1, a distance d1 between the through holes H1 in the first direction X and a distance d2 between the through holes H1 in the second direction Y may be substantially the same as each other. However, the present invention is not limited thereto, and, in the plurality of through holes H1, the distance d1 between the through holes H1 in the first direction X and the distance d2 between the through holes H1 in the second direction Y may be different from each other. In an embodiment, the through holes H1 are arranged substantially regularly on a plane, thereby uniformly or substantially uniformly maintaining the thermal conductivity in the support member 10 in the horizontal direction.

The planar shape of the through hole H1 is not particularly limited, and may be circular as shown in FIG. 4. In this specification, the planar shape of the through hole H1 refers to a shape of a cross-section obtained by cutting the through hole H1 in a direction perpendicular to the third direction Z.

The through hole H1 may extend substantially in the third direction Z (thickness direction). The planar area of the through hole H1 may be substantially uniform depending on the position in the third direction Z. In this specification, the planar area of the through hole H1 refers to an area of a figure having a shape corresponding to the planar shape of the through hole H1. For example, when the through hole H1 has a circular planar shape, an inner wall of the through hole H1 may be substantially perpendicular to one surface of the support member 10, and the through hole H1 may have a cylindrical shape as a whole. However, the present invention is not limited thereto, and the inner wall of the through hole H1 may be disposed so as to be inclined with respect to one surface of the support member 10.

The radiation member 20 is inserted and disposed in the through hole H1. The heat radiation member 20 may serve to radiate the heat generated in the display panel 100 to the outside. The heat radiation members 20 may have a planar arrangement corresponding to that of the plurality of through holes H1, and may have a shape filling the plurality of through holes H1. The heat radiation member 20 may have any of various shapes depending on the shape of the through hole H1. For example, when the through hole H1 has a cylindrical shape, the heat radiation member 20 may have a cylindrical shape corresponding to the shape of the through hole H1.

The heat radiation member 20 may be provided in the through hole H1 to be brought into direct contact with the inner wall of the through hole H1. That is, the volume of the heat radiation member 20 may be substantially similar to the volume of the through hole H1. However, in an embodiment, the heat radiation member 20 may be inserted into the through hole H1 and, thus, may have a smaller volume than the through hole H1. A thickness of the heat radiation member 20 may be substantially the same as a thickness of the through hole H1. That is, an upper surface and a lower surface of the heat radiation member 20 may be substantially aligned with an upper surface 10a and a lower surface 10b of the support member 10, respectively.

The heat radiation member 20 may be made of a material having excellent thermal conduction or thermal diffusion. For example, the heat radiation member 20 may contain a metal such as copper, a copper alloy, silver, or aluminum, which has excellent thermal conductivity, or may contain graphite, carbon nanotubes, or the like. In an embodiment, the thermal conductivity of the heat radiation member 20 may be higher than the thermal conductivity of the support member 10. In an embodiment, for example, the thermal conductivity of the support member 10 made of stainless steel is about 16 to 25 W/mk, and the thermal conductivity of the heat radiation member 20 containing graphite may be about 1500 W/m·k.

A total proportion of the heat radiation members 20 to the support member 10 in the second panel lower sheet 300 may be about 70% to 90%. That is, a ratio of the heat radiation members 20 to the support member 10 may be about 70:30 to about 90:10. When the area occupied by the heat radiation member 20 is 70% or more of the support member 10, sufficient heat conductivity can be ensured, such that the heat generated inside the display panel 100 can be easily discharged to the outside. Accordingly, the internal temperature of the display panel 100 is lowered, and deterioration of the display panel 100 can be prevented or substantially prevented. When the area occupied by the heat radiation member 20 is 90% or less of the support member 10, the function of the support member 10 can be maintained while securing high thermal conductivity. When an excessive number of through holes H1 are formed in the support member 10, the strength of the support member 10 cannot be maintained, and thus supporting performance and mechanical strength may be deteriorated. In this respect, the ratio of the heat radiation member 20 and the support member 10 may be 90:10 or less.

In consideration of the ratio of the heat radiation member 20 and the support member 10, the number of the through holes H1 may be in a range of 10 to 20. However, the present invention is not limited thereto, and the number of the through holes H1 may be 9 or less or 21 or more depending on the size of the support member 10 and the shape of the through holes H1.

In an embodiment, the heat radiation member 20 may be provided in the form of a sheet. In this case, the sheet may be cut and used in a suitable size and shape before being provided in the support member 10.

In another embodiment, the heat radiation member 20 may be provided in the form of a fluid containing a raw material and having viscosity. For example, the heat radiation member 20 may be provided in the form of a dispersion in which graphite is dispersed in a solvent having viscosity. The solvent may have adhesiveness. In this case, the heat radiation member 20 can be attached to the support member 10 without a separate bonding member. The heat radiation member 20 may be deformed and fixed so as to have a shape corresponding to the shape of the through hole H1 according to fluid characteristics.

A protective layer array 30 may be disposed on both sides of the support member 10. Specifically, the protective layer array 30 may include the first protective layer 31 and the second protective layer 32. The first protective layer 31 may be disposed on the upper surface 10a of the support member 10, and the second protective layer 32 may be disposed on the lower surface 10b of the support member 10. A lower surface of the first protective layer 31 may be in contact with the upper surface 10a of the support member 10 and the upper surface of the heat radiation member 20. An upper surface of the second protective layer 32 may be in contact with the lower surface 10b of the support member 10 and the lower surface of the heat radiation member 20.

The protective layer array 30 can prevent or substantially prevent the heat radiation member 20 from being separated from the support member 10, and can protect the heat radiation member 20 from foreign matter. Further, when the heat radiation member 20 is provided in a form having fluidity, the protective layer array 30 can prevent or substantially prevent the heat radiation member 20 from overflowing to the outside of the through hole H1.

The protective layer array 30 may contain a non-conductive material. In this case, it is possible to prevent or substantially prevent a short circuit from occurring between the display panel 100 and the heat radiation member 20.

In an embodiment, the protective layer array 30 may be formed by applying a coating solution onto the upper surface 10a and/or lower surface 10b of the support member 10 and curing or drying the applied coating solution.

In an embodiment, the protective layer array 30 may be a light blocking layer having a specific color. However, the present invention is not limited thereto, and the protective layer array 30 may be transparent. In an embodiment, the first protective layer 31 may be colored, and the second protective layer 32 may be transparent. In another embodiment, both the first protective layer 31 and the second protective layer 32 may be colored. In an exemplary embodiment, the first protective layer 31 may have a silver color that is substantially similar to stainless steel that is a material of the support member 10.

When the first protective layer 31 is a light blocking layer, it is possible to prevent or substantially prevent the light emitted from the display panel 100 from leaking to the outside. Further, it is possible to prevent or substantially prevent a pattern of the support member 10 and the heat radiation member 20 disposed under the first protective layer 31 from being visually recognized from the side of a display surface, thereby improving an aesthetic sense.

For example, in a case in which the substrate 110 of the display panel 100 and the first panel lower sheet 200 are transparent, a part of the light emitted from the display panel 100 passes through the substrate 110 and the first panel lower sheet 200 and then reaches the second panel lower sheet 300. The light may be absorbed or reflected at different ratios depending on the configuration of the support member 10 and the radiation member 20. That is, in an embodiment, the reflectance of the heat radiation member 20 made of graphite is lower than that of the support member 10 made of stainless steel, and the heat radiation member 20 made of graphite absorbs a larger amount of light than the support member 10 made of stainless steel. As a result, a difference in contrast due to the heat radiation member 20 may occur on the side of the display surface of the display device 1. Such a difference in contrast may cause a user to be perceived as a shade, thereby deteriorating an aesthetic sense. When the protective layer array 30 (for example, the first protective layer 31) disposed between the display panel 100 and the heat radiation member 20 functions as a colored light blocking layer, most of the light traveling under the display panel 100 is absorbed or reflected by the first protective layer 31, and thus does not reach the support member 10 and the heat radiation member 20. Therefore, the light is uniformly or substantially uniformly reflected or absorbed over the entire display device 1, such that the display device 1 can ensure uniform or substantially uniform luminance without a difference in shade. In addition, it is possible to prevent or substantially prevent light from leaking toward the lower side of the display panel 100.

The thickness of the second panel lower sheet 300 depends on the thickness of the support member 10 and the thickness of the protective layer array 30. That is, the heat radiation member 20 does not affect the thickness of the second panel lower sheet 300.

If a heat radiation member were simply stacked on the support member 10, the thickness of a second panel lower sheet would be adjusted by the thickness of the support member 10, a thickness of the heat radiation member, and the thickness of the protective layer array 30. In this case, the thickness of the second panel lower sheet may be increased by the thickness of the heat radiation member. In contrast, according to embodiments of the present invention, the heat radiation member 20 is disposed to be inserted into the through hole H1, and the heat radiation member 20 may not affect the thickness of the second panel lower sheet 300. That is, the second panel lower sheet 300 can perform both a heat radiation function and a supporting function without an increase in thickness. Thus, the display device 1 according to an embodiment may have improved durability while satisfying slimness, thinness, and weight reduction.

In an embodiment, the thickness of the second panel lower sheet 300 may be about 0.05 mm to about 0.1 mm. When the thickness of the second panel lower sheet 300 is 0.05 mm or more, the support member 10 can secure sufficient strength to support the display panel 100, despite the area removed by the through holes H1. As the thickness of the support member 10 increases, the strength of the support member 10 increases, and thus the display panel 100 can be more sufficiently supported. However, when the thickness of the supporting member 10 excessively increases, the display device 1 may be problematic in slimness and thinness. In this respect, the thickness of the second panel lower sheet 300 may be about 0.1 mm or less.

Herein, some other embodiments will be described. In the following embodiments, a description of the same configurations as those of the previously described embodiment will be omitted or simplified, and differences will be mainly described.

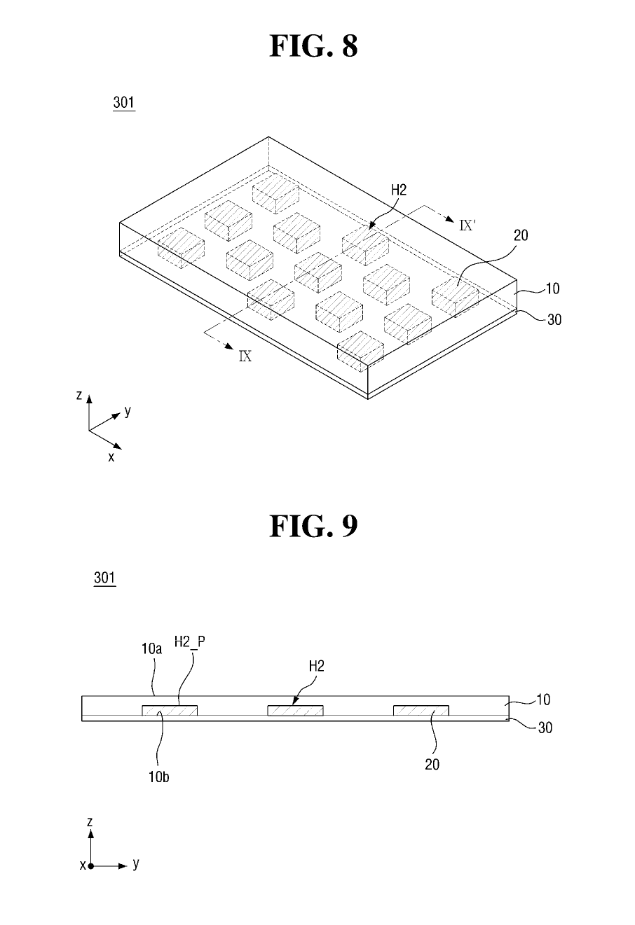

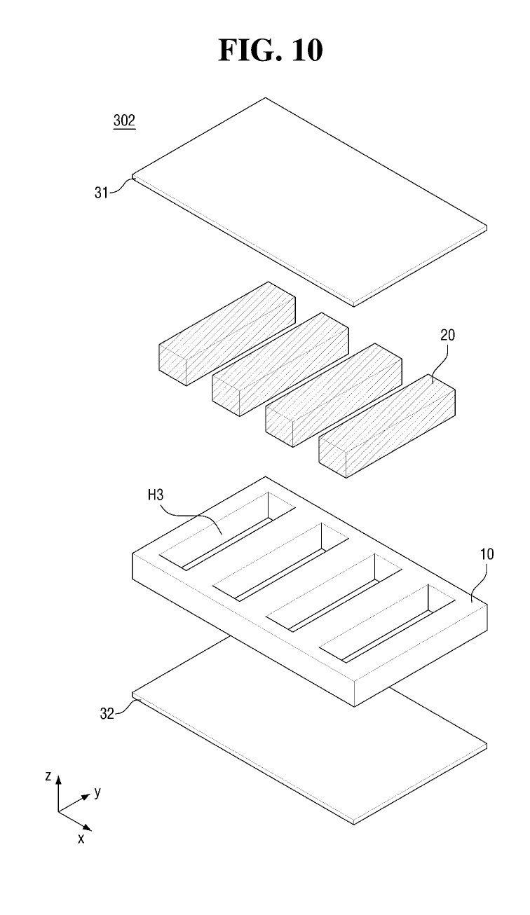

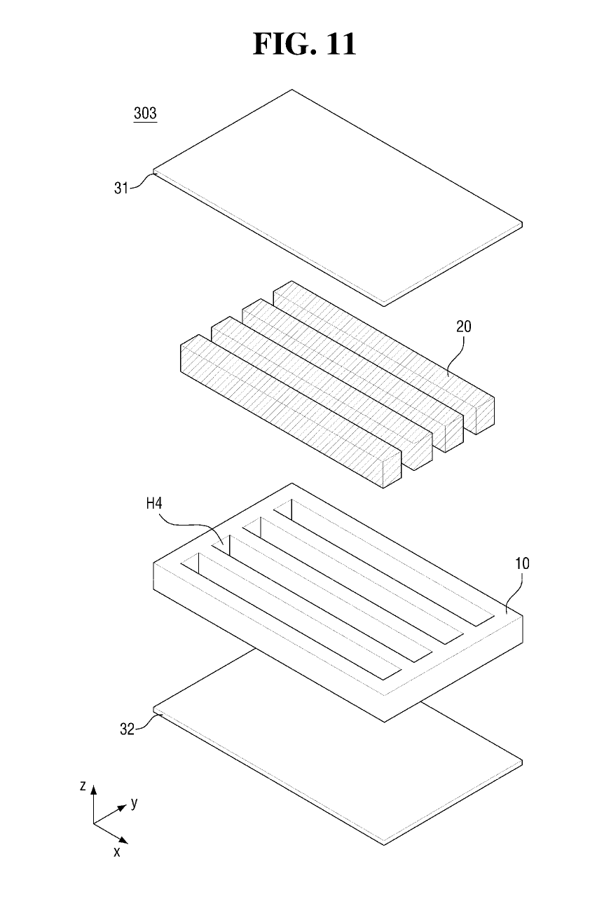

FIG. 7 is an exploded perspective view of a second panel lower sheet according to another embodiment. FIG. 8 is a perspective view of the second panel lower sheet of FIG. 7. FIG. 9 is a cross-sectional view of the second panel lower sheet of FIG. 7, taken along the line IX-IX′ of FIG. 8.

Referring to FIGS. 7 to 9, a second panel lower sheet 301 according to another embodiment may include concave grooves H2. The second panel lower sheet 300 according to the embodiment of FIG. 1 is different from the second panel lower sheet 301 according to the embodiment of FIG. 7 in that the second panel lower sheet 300 includes the through holes H1.

The concave grooves H2 may be formed in one surface of a support member 10 of the second panel lower sheet 301, for example, a lower surface 10b thereof. The concave groove H2 extends from the lower surface 10b of the support member 10 substantially in the third direction Z, but does not extend to an upper surface 10a of the support member 10. In an embodiment, the upper surface 10a of the support member 10 may be smooth because it does not include irregularities such as the concave grooves H2. When the upper surface 10a of the support member 10 does not include irregularities, the upper surface 10a of the support member 10 can perform a function similar to that of the first protective layer 31. That is, the contrast due to the color difference between the heat radiation member 20 and the support member 10 is not recognized on the side of the display surface of the display device 1, such as to improve the aesthetic sense of the display device 1. However, the present invention is not limited thereto, and the concave grooves H2 may be formed in the upper surface 10a of the support member 10.

In an embodiment, the concave groove H2 may have a square pillar shape. That is, the concave groove H2 may have a quadrangular shape in a plan view, and the inner wall of the concave groove H2 may be substantially perpendicular to one surface of the support member 10. In an embodiment, a base surface H2_P of the concave groove H2 may be flat, and may be substantially parallel to a surface of the support member 10. However, the present invention is not limited thereto, and the concave groove H2 may have a dome shape, and the base surface H2_P thereof may be a curved surface.

In an embodiment, the concave grooves H2 are regularly arranged on a plane, and may be disposed to be spaced apart from each other in a direction intersecting the first direction X and the second direction Y and forming an acute angle. However, the present invention is not limited thereto, and the concave grooves H2, similarly to the aforementioned through holes H1, may be arranged in a substantially matrix shape.

The concave grooves H2, similarly to the aforementioned through holes H1, provide spaces in which the heat radiation members 20 are inserted. The base surface H2_P of the concave groove H2 may support the heat radiation member 20. In an embodiment, for example, when the heat radiation member 20 is provided in the form of a sheet, an adhesive member is interposed between the base surface H2_P and the heat radiation member 20 to help the support member 10 and the heat radiation member 20 be coupled with each other. Thus, the first protective layer 31 to be disposed on the upper surface 10a of the support member 10 may be omitted.

A protective layer 30 may be disposed on the lower surface 10b of the support member 10. The protective layer 30 can prevent or substantially prevent the heat radiation member 20 from being separated from the support member 10. In addition, the protective layer 30 can prevent or substantially prevent foreign matter from penetrating into the support member 10.

A total thickness of the second panel lower sheet 301 may be reduced because the protective layer 30 is not disposed on the upper surface 10a of the support member 10. Further, a thickness of the support member 10 may be increased by the thickness of the protective layer 30 while maintaining the thickness of the second panel lower sheet 301.

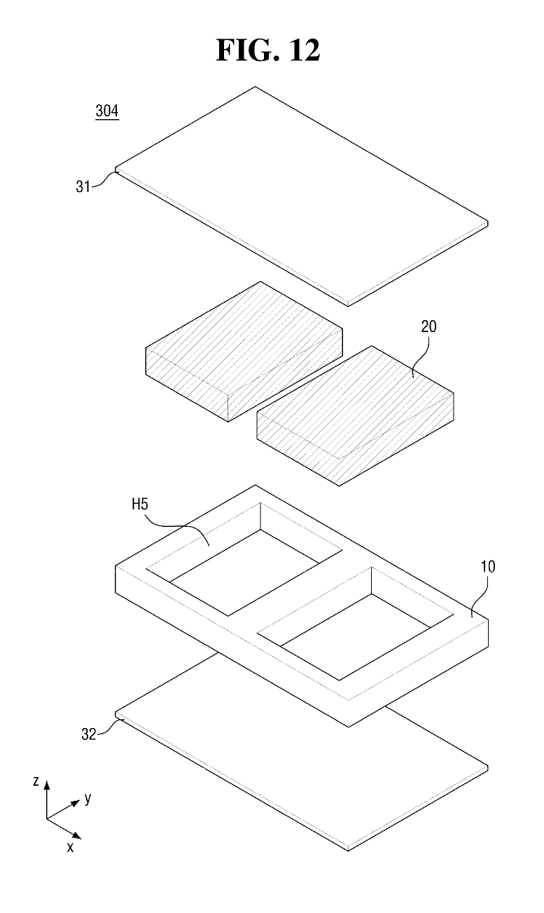

FIGS. 10 to 12 are perspective views showing shapes and arrangements of through holes of second panel lower sheets according to various embodiments.

FIG. 10 illustrates a case in which a through hole H3 of a second panel lower sheet 302 has a rectangular shape on a plane, and has a rectangular or square pillar shape as a whole. The through hole H3 may have a bar shape as a whole.

In an embodiment, the through hole H3 may have a rectangular shape in which long sides are disposed along the width direction of the support member 10, for example, along the second direction Y, and short sides are disposed along the first direction X.

A second panel lower sheet 303 according to an embodiment of FIG. 11 is different from the second panel lower sheet 302 according to an embodiment of FIG. 10 in that the planar shape of a through hole H4 of the second panel lower sheet 303 is a rectangular shape in which long sides are disposed along the first direction X.

In the planar shape of the through hole H4 of the second panel lower sheet 303, long sides are disposed along the length direction of the support member 10, for example, along the first direction X, and short sides are disposed along the second direction Y.

In a second panel lower sheet 304 according to an embodiment of FIG. 12, two through holes H5 may be disposed.

The number of the through holes H5 is smaller than the number of the through holes H3 according to an embodiment of FIG. 10 or the number of the through holes H4 according to an embodiment of FIG. 11, whereas the area of each of the through holes H5 is relatively increased, such that a ratio of the heat radiation member 20 to the entire support member 10 may be maintained.

In the case of the aforementioned embodiments of FIGS. 10 to 12, there is illustrated a case in which the support member 10 is provided with the through holes H3, the through holes H4, or the through holes H5, but concave grooves may also be disposed instead of the through holes H3, the through holes H4, or the through holes H5. That is, the concave grooves may have a rectangular shape having a long side extending in the long side or short side direction of the support member 10, and may have a rectangular column shape as a whole.

Further, the number of the concave grooves may be relatively decreased, but the area of each of the concave grooves may be relatively increased, such that a ratio of the concave grooves to the support member 10 may be maintained.

The through holes H1, the through holes H3, the through holes H4, the through holes H5, or the concave grooves H2 arranged in the support member 10 are not limited to the above-mentioned examples, and may have various shapes and arrangements in consideration of the ratio of the heat radiation member 20 to the support member 10.

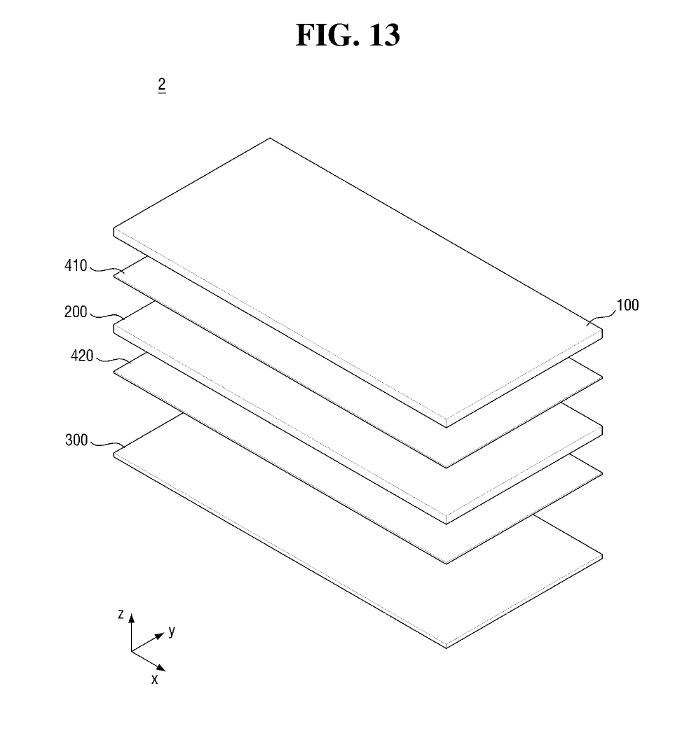

FIG. 13 is an exploded perspective view of a display device according to another embodiment.

Referring to FIG. 13, a display device 2 according to another embodiment may include only a flat area FA without a bending area BA. The display device 2 of FIG. 13 is different from the display device 1 of FIG. 1 in which the display panel 100 and the first panel lower sheet 200 are disposed over the flat area FA and the bending area BA. That is, the display panel 100 and the first panel lower sheet 200 of the display device 2 of FIG. 13 may be disposed in only the flat area FA.

The display panel 100, the first panel lower sheet 200, and the second panel lower sheet 300 may have substantially a same size. The side surfaces of the display panel 100, the first panel lower sheet 200, and the second panel lower sheet 300 may be substantially aligned. However, the present invention is not limited thereto, and, in one side of the display device 2, the side surfaces of the first panel lower sheet 200 and the second panel lower sheet 300 may be disposed inside the side surface of the display panel 100.

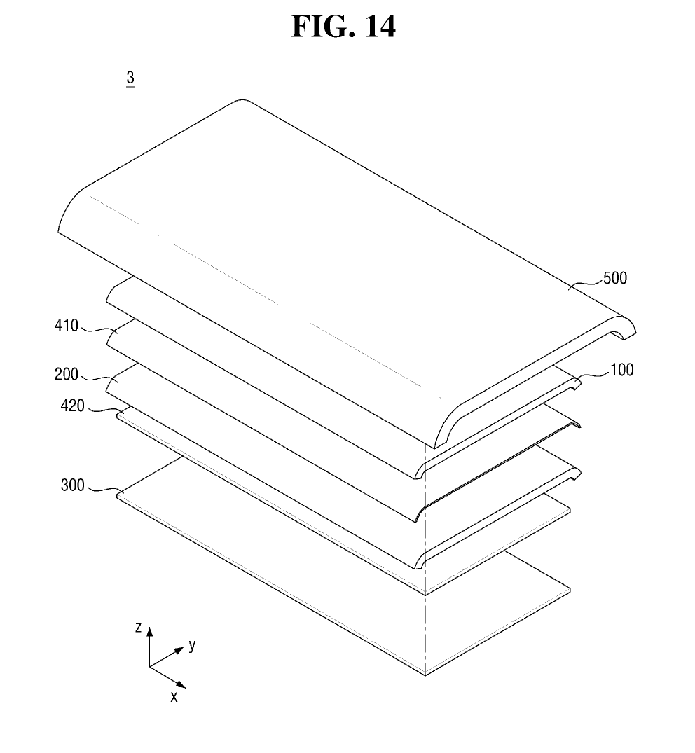

FIG. 14 is an exploded perspective view of a display device according to another embodiment.

Referring to FIG. 14, a display device 3 may further include a window 500 disposed on the display panel 100.

The window 500 is disposed on the display panel 100. The window 500 protects the display panel 100 while transmitting the light emitted from the display panel 100. The window 500 may be made of glass or the like, or may be made of a plastic material, such as polyimide.

The window 500 may be disposed to overlap the display panel 100 and may cover a surface (e.g., an entire surface) of the display panel 100. In an embodiment, the window 500 may be larger than the display panel 100. For example, at both edges of the display device 3, the window 500 may protrude outward from the display panel 100. That is, a side surface of the display panel 100 may be disposed on the inner side with respect to a corresponding side surface of the window 500.

In an embodiment, the window 500 may be disposed over the bending area BA and the flat area FA. A bending degree of the window 500 may be substantially the same as a bending degree of the display panel 100, and the window 500 and the display panel 100 may be disposed closely to each other without a space.

The display device 3 may display a screen over the flat area FA and the bending area BA. That is, a display area may include not only the flat area FA but also the bending area BA, such that a range in which a user recognizes the display area may be extended.

In an embodiment, a touch member (not shown) may be disposed between the display panel and the window 500. The touch member may be a panel type touch member or a film type touch member. The touch member may have substantially the same size as the display panel 100, and may be disposed to overlap the display panel 100. The touch member may be disposed over the bending area BA and the flat area FA. A side surface of the touch member and a corresponding side surface of the display panel may be aligned, but the present invention is not limited thereto.

The touch panel 100 and the touch member, or the touch member and the window 500, may be attached to each other by a transparent bonding layer (not shown) such as an optical clear adhesive (OCA) or an optical clear resin (OCR). When the touch member is not disposed, the display panel 100 and the window 500 may be attached to each other by an optical clear adhesive (OCA) or an optical clear resin (OCR). In some embodiments, the display panel 100 may be provided therein with a touch electrode unit.

The first panel lower sheet 200 and the second panel lower sheet 300 may be disposed under the display panel 100. The upper portion of the display panel 100 may be protected by the window 500, and the lower portion of the display panel 100 may be protected by the first panel lower sheet 200 and the second panel lower sheet 300.

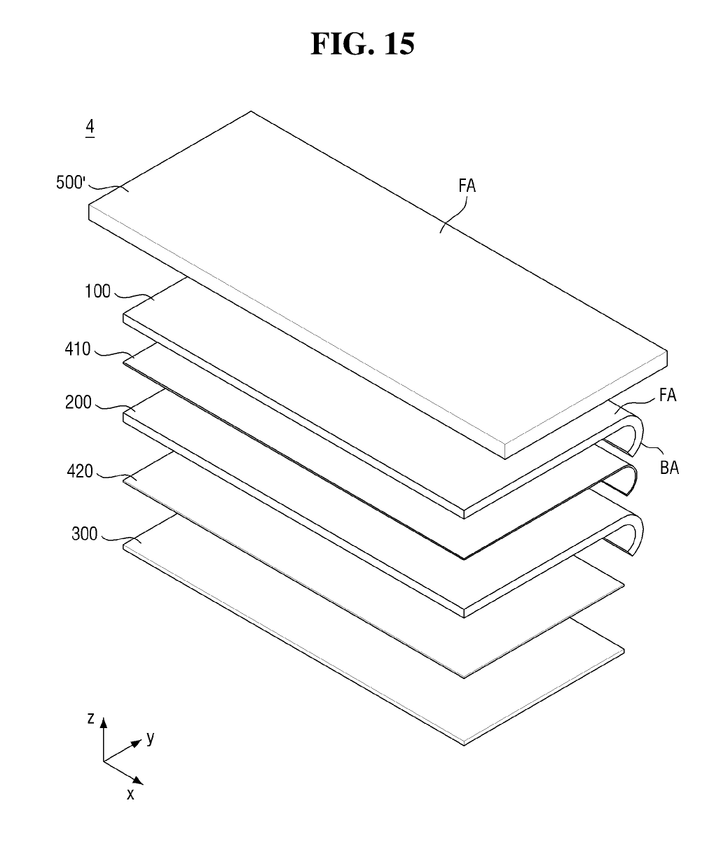

FIG. 15 is an exploded perspective view of a display device according to another embodiment.

Referring to FIG. 15, a display device 4 may include a window 500′ composed of only the flat area FA without including the bending area BA.

The window 500′ may be disposed to overlap the display panel 100 and may cover a surface (e.g., an entire flat surface) of the display panel 100. The window 500′ may be larger than the display panel 100 on a plane. The size of the flat area FA, that is, the size of the display panel 100 excluding the bending area BA may be smaller than the size of the window 500′. In an embodiment, an area where a screen is substantially displayed outside the display device 4 may be limited to the flat area FA of the display panel 100.

In an embodiment, the bending area BA of the display panel 100 is bent downward from a plane where the flat area FA is located, such that one side of the display panel 100 may be located on the lower surface of the display panel 100. The bending area BA of the display panel 100 may be a non-display area that does not display a screen.

A driving chip (not shown) for driving the display panel 100 may be disposed on the bending area BA of the display panel 100. The driving chip of the display panel 100 may act as a heat generating element that generates heat when driven. The heat generated in the driving chip can be effectively radiated by the second panel lower sheet 300 disposed adjacent to the driving chip.

The first panel lower sheet 200 and the second panel lower sheet 300 may be disposed under the display panel 100. The first panel lower sheet 200 may be disposed over the bending area BA and the flat area FA. A bending degree of the first panel lower sheet 200 may be substantially the same as a bending degree of the display panel 100, and the first panel lower sheet 200 and the display panel 100 may be disposed closely to each other without a space.

In an embodiment, the second panel lower sheet 300 may be disposed only in the flat area FA, and may not be disposed in the bending area BA. The lower surface of the display panel 100, disposed in the bending area BA, may be disposed adjacent to the lower surface 300b (see FIG. 2) of the second panel lower sheet 300.

FIG. 15 illustrates a case in which the bending area BA is disposed at one long side of the display device 4, but the bending area BA may also be disposed at one short side of the display device 4.

Moreover, FIGS. 1, 14, and 15 illustrate a case in which the bending area BA is disposed at both long sides or one long side of each of the display devices 1, 3, and 4, but the present invention is not limited thereto, and each of the display devices 1, 3, and 4 may be a sloped display device in which the bending area BA is disposed at both long sides and both short sides thereof.

As described above, according to an embodiment of the present invention, the heat radiation member is inserted in the through hole formed in the support member, such that the support function and heat radiation function of the display panel can be secured without increasing the thickness of the display device.

According to another embodiment of the present invention, the heat radiation member is inserted in the concave groove formed in the support member, such that the support function and heat radiation function of the display panel can be secured without increasing the thickness of the display device.

The aspects and effects of the present invention are not limited by the foregoing, and other various aspects and effects are anticipated herein. Although some exemplary embodiments of the present invention have been disclosed for illustrative purposes, those skilled in the art will appreciate that various modifications, additions, and substitutions are possible, without departing from the scope and spirit of the present invention as disclosed in the accompanying claims.

What is claimed is:

1. A display device comprising:
a display panel including a flat area and a bending area located around the flat area; and
a panel lower sheet arranged on the display panel and overlapping the flat area,
wherein the panel lower sheet includes a support member including at least one through hole and a heat radiation member arranged in the at least one through hole.

2. The display device of claim 1, wherein the panel lower sheet does not overlap the bending area.

3. The display device of claim 1, wherein an area of the heat radiation member is 70% to 90% of an area of the support member.

4. The display device of claim 1, wherein a thermal conductivity of the heat radiation member is higher than a thermal conductivity of the support member.

5. The display device of claim 4, wherein the support member comprises stainless steel.

6. The display device of claim 5, wherein the heat radiation member comprises graphite, copper, or carbon nanotubes.

7. The display device of claim 6, further comprising a non-conductive bonding layer between the display panel and the panel lower sheet.

8. The display device of claim 1, further comprising a protective layer arranged between the display panel and the panel lower sheet and being in contact with the heat radiation member.

9. The display device of claim 8, wherein the protective layer has a same color as the support member.

10. The display device of claim 1, further comprising a buffering member between the display panel and the panel lower sheet.

11. The display device of claim 10, wherein the buffering member is arranged over the bending area and the flat area.

12. The display device of claim 11, wherein the buffering member comprises polyethylene terephthalate, polyimide, or polyethylene.

13. The display device of claim 1, wherein a thickness of the support member is substantially the same as a thickness of the heat radiation member.

14. A display device comprising:
a display panel including a flat area and a bending area located around the flat area; and
a panel lower sheet arranged on the display panel and overlapping the flat area,
wherein the panel lower sheet includes a support member including at least one concave groove and a heat radiation member arranged in the at least one concave groove.

15. The display device of claim 14,
wherein the support member includes a first surface facing the display panel and a second surface facing the first surface, and
the at least one concave groove is formed in the second surface.

16. The display device of claim 15, further comprising a protective layer arranged on the second surface of the support member and being in contact with the heat radiation member.

17. The display device of claim 14, wherein an area of the heat radiation member is 70% to 90% of an area of the support member.

18. The display device of claim 14, wherein a thermal conductivity of the heat radiation member is higher than a thermal conductivity of the support member.

19. The display device of claim 18, wherein the support member comprises stainless steel.

20. The display device of claim 14, wherein the panel lower sheet does not overlap the bending area.
